(19) United States
(12) Patent Application Publication
(10) Pub. No.: US 2026/0204324 A1
(43) Pub. Date: Jul. 16, 2026

(54) MEMORY DEVICE AND READING METHOD THEREOF

(71) Applicant: MACRONIX International Co., Ltd., Hsinchu (TW)

(72) Inventors: Wen-Ching Hsiao, Hsinchu City (TW); Chun-Hsiung Hung, Hsin-Chu (TW); Shuo-Nan Hung, Hsinchu County (TW)

(73) Assignee: MACRONIX International Co., Ltd., Hsinchu (TW)

(21) Appl. No.: 19/177,650

(22) Filed: Apr. 14, 2025

Related U.S. Application Data
(60) Provisional application No. 63/745,322, filed on Jan. 15, 2025.

(51) Int. Cl. G11C 16/26; G11C 16/08; G11C 16/20; G11C 16/32

(52) U.S. Cl. CPC G11C 16/26; G11C 16/08; G11C 16/20; G11C 16/32

(57) ABSTRACT

A memory device and a reading method thereof are provided. The memory device is, for example a three dimensional NAND flash memory circuit, and provides a storage media with high-performance and high-capacity. The reading method includes: during a setup period, setting a plurality of word line signals to a set voltage value, wherein each of the word line signals is commonly received by a plurality of memory sub-blocks; during a plurality of reading periods, setting a selected word line signal of the word line signals to a selected voltage value, and setting at least one deselected word line signal of the word line signals to a deselected voltage value; and during each of the reading periods, selecting each of the memory sub-blocks to perform a reading operation, wherein the reading periods are a plurality of consecutive time periods after the setup period.

### CROSS-REFERENCE TO RELATED APPLICATION

This application claims the priority benefit of U.S. provisional application Ser. No. 63/745,322, filed on Jan. 15, 2025. The entirety of the above-mentioned patent application is hereby incorporated by reference herein and made a part of this specification.

### BACKGROUND

### Technical Field

The disclosure relates to a memory device and a reading method thereof, and particularly relates to a memory device and a reading method thereof that may improve reading efficiency.

### Description of Related Art

In conventional memory devices, when executing a data reading operation, it is necessary to perform complete setting, reading, and recovery operations for the selected word line signal. When switching the selected word line signal, the setting, reading, and recovery operations need to be repeatedly performed. Therefore, regardless of whether the reading operation is performed on the same or different memory blocks, each data acquisition requires time spent on the setting and recovery operations, causing delay in the reading operation and reducing the use efficiency of the memory device.

### SUMMARY

The disclosure provides a memory device and a reading method thereof, which may improve the operating speed of the sequential reading operation.

A reading method of the disclosure includes: during a setup period, setting a plurality of word line signals to a set voltage value, wherein each of the word line signals is commonly received by a plurality of memory sub-blocks; during a plurality of reading periods, setting a selected word line signal of the word line signals to a selected voltage value, and setting at least one deselected word line signal of the word line signals to a deselected voltage value; and during each of the reading periods, selecting each of the memory sub-blocks to perform a reading operation, wherein the reading periods are a plurality of consecutive time periods after the setup period.

A memory device of the disclosure includes a memory block and a controller. The memory block includes a plurality of memory sub-blocks. The memory block receives a plurality of word line signals through a plurality of word lines respectively, wherein each of the word line signals is commonly received by the plurality of memory sub-blocks, and the memory sub-blocks respectively receive a plurality of memory string selection signals. The controller is coupled to the memory block to perform the reading method.

Based on the foregoing, in the memory device of the disclosure, when executing a reading operation of the memory block, the individual memory sub-blocks may be selected without sequence limitation after the setup period to perform the sequential reading operation by providing a selected word line signal with a selected voltage value to the memory cells being read. In this way, the word line signal, during the reading operation process, may avoid repetitive pull-up and pull-down operations, thereby effectively improving the operating speed of the reading operation.

### BRIEF DESCRIPTION OF THE DRAWINGS

FIG. 1 is a schematic diagram of a memory device according to an embodiment of the disclosure.

FIG. 2 is a schematic diagram of an implementation of a memory sub-block according to an embodiment of the disclosure.

FIG. 3 to FIG. 6 are waveform diagrams of different implementations of a reading operation of a memory device according to embodiments of the disclosure.

FIG. 7 is a flowchart of a reading method of a memory device according to an embodiment of the disclosure.

### DESCRIPTION OF THE EMBODIMENTS

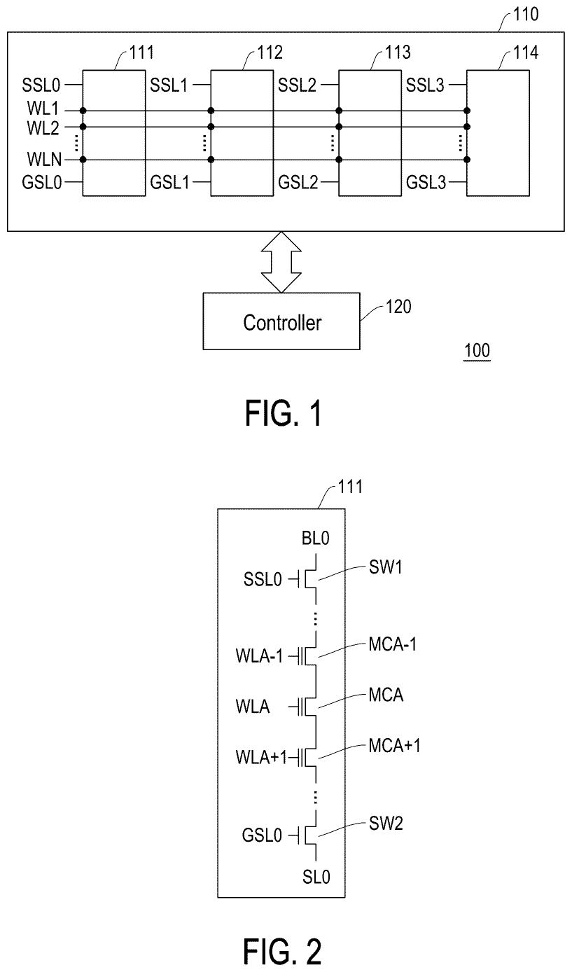

Referring to FIG. 1, FIG. 1 is a schematic diagram of a memory device according to an embodiment of the disclosure. A memory device 100 includes one or more memory blocks 110 and a controller 120. The memory block 110 includes a plurality of memory sub-blocks 111 to 114. In this embodiment, the memory sub-blocks 111 to 114 respectively receive memory string selection signals SSL0 to SSL3, and ground selection signals GSL0 to GSL3. The memory sub-blocks 111 to 114 also commonly receive word line signals WL1 to WLN.

It is worth mentioning that the plurality of memory sub-blocks 111 to 114 may be disposed in the memory block 110. In the embodiment of the disclosure, there is no particular limitation on the number of the memory sub-blocks. The 4 memory sub-blocks 111 to 114 in the memory block 110 shown in FIG. 1 are merely an illustrative example and should not be used to limit the implementation scope of the disclosure.

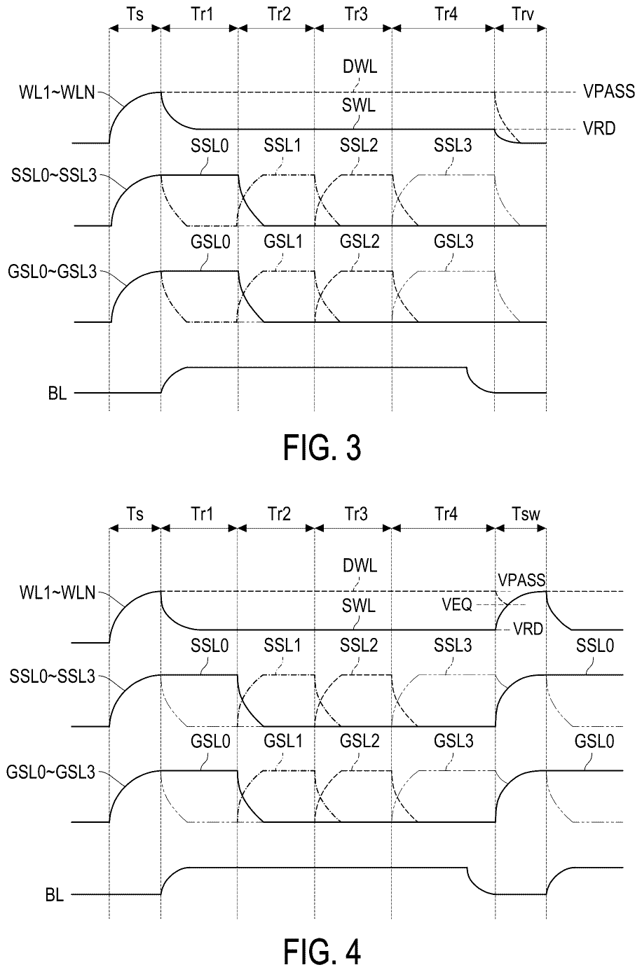

For the implementation details of each of the memory sub-blocks 111 to 114, reference may be made to FIG. 2, which is a schematic diagram of an implementation of a memory sub-block according to an embodiment of the disclosure. Taking the memory sub-block 111 as an example, the memory sub-block 111 includes a memory string selection switch SW1, a ground selection switch SW2, and a plurality of memory cells MCA−1 to MCA+1. The memory cells MCA−1 to MCA+1 are coupled in series between the memory string selection switch SW1 and the ground selection switch SW2. One end of the memory string selection switch SW1 is coupled to a bit line BL0, and the other end of the memory string selection switch SW1 is coupled to the memory cells MCA−1 to MCA+1. A control terminal of the memory string selection switch SW1 receives the corresponding memory string selection signal SSL0. One end of the ground selection switch SW2 is coupled to a source line SL0, and the other end of the ground selection switch SW2 is coupled to the memory cells MCA+1 to MCA−1. A control terminal of the ground selection switch SW2 receives the corresponding ground selection signal GSL0.

In this embodiment, the memory string selection switch SW1 and the ground selection switch SW2 may both be switches formed by transistors or floating gate transistors, while the memory cells MCA+1 to MCA−1 may be constructed respectively through a plurality of floating gate transistors. The memory cells MCA+1 to MCA−1 may be flash memory cells.

In actual operation, when performing a reading operation on the memory cells MCA+1 to MCA−1 on the memory sub-block 111, the memory string selection signal SSL0 and the ground selection signal GSL0 may be set to an enabled state (for example, logic value 1) to enable conduction of both the memory string selection switch SW1 and the ground selection switch SW2. Taking the selection of memory cell MCA as the selected read memory cell as an example, the memory cells MCA+1 and MCA−1 are both deselected read memory cells. The memory device 100 may set a word line signal WLA received by the memory cell MCA as a selected word line signal, and set the word line signal WLA as the selected word line signal to a selected voltage value; and set word line signals WLA+1 and WLA−1 respectively received by the memory cells MCA+1 and MCA−1 as deselected word line signals, and set the word line signals WLA+1 and WLA−1 as the deselected word line signals to a deselected voltage value. In this embodiment, the selected voltage value is a voltage value that may enable the corresponding memory cell to generate reading current according to the stored data, while the deselected voltage value is a voltage value that may enable the corresponding memory cell to be fully conductive to reduce the provided equivalent resistance to a relatively low value. The deselected voltage value may be the voltage value of the pass voltage (VPASS), and in this embodiment, the deselected voltage value may be greater than the selected voltage value.

Referring again to FIG. 1, when performing a reading operation on the memory block 110, the memory device 100 may first enter a setup period. During the setup period, the controller 120 may set the word line signals WL1 to WLN to the same set voltage value by pulling up the voltage values of the word line signals WL1 to WLN. This set voltage value may be equal to the voltage value of the aforementioned pass voltage. Then, after the setup period, the controller may first enter a plurality of consecutively occurring reading periods. When entering the reading period, the controller 110 may select one of the word line signals WL1 to WLN (taking the word line signal WL1 as an example) as the selected word line signal, and set the remaining word line signals (the word line signals WL2 to WLN) as the deselected word line signals. Moreover, the controller 120 may set the word line signal WL1 to the selected voltage value, and set the word line signals WL2 to WLN to the deselected voltage value (equal to the voltage value of the pass voltage).

In the first reading period, the controller 120 may select the memory sub-block 111 to perform a reading operation on the memory cell receiving the selected word line signal (the word line signal WL1) by enabling the memory string selection signal SSL0 and the ground selection signal GSL0, and setting the memory string selection signals SSL1 to SSL3 and the ground selection signals GSL1 to GSL3 to a disabled state. Then, in the second reading period, the controller 120 may change to enable the memory string selection signal SSL1 and the ground selection signal GSL1, and set the memory string selection signals SSL0, SSL2, and SSL3 and the ground selection signals GSL0, GSL2, and GSL3 to a disabled state, so as to select the memory sub-block 112 to perform a reading operation on the memory cell receiving the selected word line signal (the word line signal WL1). Similarly, the controller 120 may sequentially select the memory sub-blocks 111 to 114 for the reading operation during a plurality of reading periods by sequentially enabling the memory string selection signals SSL0 to SSL3 and the ground selection signals GSL0 to GSL3.

It is worth noting that, in this embodiment, during the plurality of reading periods, the voltage values of the word line signals WL1 to WLN do not change, regardless of whether they are the selected word line signals or the deselected word line signals. Therefore, the reading operations sequentially performed on the memory sub-blocks 111 to 114 may be performed in rapid succession, effectively improving the speed of the reading operation.

Incidentally, in this embodiment, the memory sub-blocks 111 to 114 may be coupled to a plurality of different bit lines respectively. The memory sub-blocks 111 to 114 may share the same source line or be coupled to different source lines, and there is no particular limit.

Besides, the controller 120 may, during one reading period, select more than one memory sub-blocks to perform reading operation by enabling multiple memory string selection signals and ground selection signals.

In this embodiment, the controller 120 may be a processor with computation capability. Alternatively, the controller 120 may be designed through a hardware description language (HDL) or any other digital circuit design method familiar to those skilled in the art, and may be a hardware circuit implemented through a field programmable gate array (FPGA), a complex programmable logic device (CPLD), or an application-specific integrated circuit (ASIC).

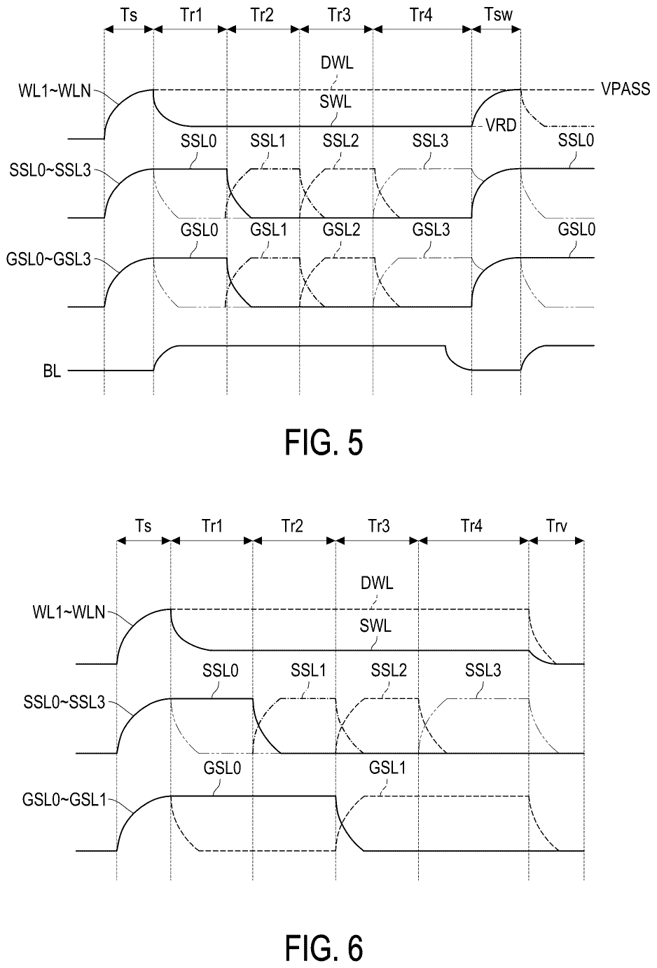

Referring to FIG. 1 and FIG. 3 in conjunction, FIG. 3 is a waveform diagram of a reading operation of a memory device according to an embodiment of the disclosure. During a setup period Ts, the controller 120 may pull all word line signals WL1 to WLN up to a set voltage value, and also pull the memory string selection signals SSL0 to SSL3 and the ground selection signals GSL0 to GSL3 up to the voltage value corresponding to logic value 1.

Subsequently, after the setup period Ts, the process may sequentially enter reading periods Tr1 to Tr4. During the reading periods Tr1 to Tr4, the controller 120 selects one of the word line signals WL1 to WLN as a selected word line signal SWL, and sets the other word line signals as deselected word line signals DWL. The controller 120 maintains the selected word line signal SWL at the selected voltage value (equal to a reading voltage VRD) during the reading periods Tr1 to Tr4, and maintains the deselected word line signals DWL at the deselected voltage value (equal to a pass voltage VPASS) during the reading periods Tr1 to Tr4. The pass voltage VPASS is greater than the reading voltage VRD.

During the reading period Tr1, the controller 120 maintains the memory string selection signal SSL0 at logic value 1, and pulls the memory string selection signals SSL1 to SSL3 down to logic value 0. The controller 120 maintains the ground selection signal GSL0 at logic value 1, and pulls the ground selection signals GSL1 to GSL3 down to logic value 0, thereby selecting the memory sub-block 111 for the reading operation. Then, during the reading period Tr2, the controller 120 changes the memory string selection signal SSL1 to logic value 1, and sets the memory string selection signals SSL0, SSL2, and SSL3 to logic value 0. The controller 120 changes the ground selection signal GSL1 to logic value 1, and pulls the ground selection signals GSL0, GSL2, and GSL3 down to logic value 0, thereby selecting the memory sub-block 112 for the reading operation.

By analogy, during the reading periods Tr3 and Tr4, the controller 120 may sequentially pull up the memory string selection signals SSL2 and SSL3, and the ground selection signals GSL2 and GSL3 to sequentially select the memory sub-blocks 113 and 114 for the reading operation.

In this embodiment, after the reading period Tr4, the process may enter a recovery period Trv. During the recovery period Trv, the controller 120 may pull down all the word line signals WL1 to WLN, the memory string selection signals SSL0 to SSL3, and the ground selection signals GSL0 to GSL3 to a reference voltage, for example, the ground voltage.

Incidentally, during the reading periods Tr1 to Tr4, the voltage value on a bit line BL may generate corresponding variations in response to the data stored in the memory cell being read.

Referring to FIG. 1 and FIG. 4 in conjunction, FIG. 4 is a waveform diagram of another implementation of a reading operation of a memory device according to an embodiment of the disclosure. The operation waveforms of the setup period Ts and the reading periods Tr1 to Tr4 are all the same as those in the embodiment of FIG. 3 and will not be repeated here. In this embodiment, after the reading period Tr4, the process may enter a switching period Tsw. During the switching period, the controller 120 may perform a preliminary operation of switching the selected word line signal SWL from the currently selected word line signal (for example, the word line signal WL1) to the next word line signal (for example, the word line signal WL2). First, the controller 120 may perform an equalization operation on the selected word line signal SWL and the deselected word line signals DWL, so as to float and couple all of world lines together to equal the voltage values of the selected word line signal SWL and the deselected word line signals DWL to a same equalization voltage value VEQ, respectively. Then, all the word line signals WL1 to WLN are pulled up to the selected voltage value (equal to the pass voltage VPASS).

After the switching period Tsw, the controller 120 may set the next word line signal (the word line signal WL2) as the selected word line signal SWL, and set the other word line signals as the deselected word line signals DWL, and set the selected word line signal SWL to the selected voltage value (equal to the reading voltage VRD), and set the deselected word line signals SWL to the deselected voltage value (equal to the pass voltage VPASS).

Referring to FIG. 1 and FIG. 5 in conjunction, FIG. 5 is a waveform diagram of another implementation of a reading operation of a memory device according to an embodiment of the disclosure. The operation waveforms of the setup period Ts and the reading periods Tr1 to Tr4 are all the same as those in the embodiment of FIG. 4 and will not be repeated here. In this embodiment, during the switching period Tsw after the reading period Tr4, the controller 120 may perform a preliminary operation of switching the selected word line signal SWL from the currently selected word line signal (for example, the word line signal WL1) to the next word line signal (for example, the word line signal WL2). Compared to the embodiment in FIG. 4, the controller 120 does not perform an equalization operation on the selected word line signal SWL and the deselected word line signals DWL, but directly pulls up the selected word line signal SWL to the selected voltage value (equal to the pass voltage VPASS). After the switching period Tsw, the controller 120 may similarly set the next word line signal (the word line signal WL2) as the selected word line signal SWL, and set the other word line signals as the deselected word line signals DWL, and set the selected word line signal SWL to the selected voltage value (equal to the reading voltage VRD), and set the deselected word line signal SWL to the deselected voltage value (equal to the pass voltage VPASS).

Referring to FIG. 1 and FIG. 6 in conjunction, FIG. 6 is a waveform diagram of another implementation of a reading operation of a memory device according to an embodiment of the disclosure. During the setup period Ts and the reading periods Tr1 to Tr4, the operation waveforms of the word line signals WL1 to WLN and the memory string selection signals SSL0 to SSL3 are all the same as those in the embodiment of FIG. 5 and will not be repeated here. In this embodiment, the memory sub-blocks 111 and 112 may share the ground selection signal GSL0, while the memory sub-blocks 113 and 114 may share the ground selection signal GSL1. Therefore, during the reading periods Tr1 and Tr2, the controller 110 may sequentially select the memory sub-blocks 111 and 112 for the reading operation by pulling down the ground selection signal GSL1 in conjunction with sequentially pulling down the memory string selection signals SSL0 and SSL1. Moreover, during the reading periods Tr3 and Tr4, the controller 110 may sequentially select the memory sub-blocks 113 and 114 for the reading operation by pulling down the ground selection signal GSL0 in conjunction with sequentially pulling down the memory string selection signals SSL2 and SSL3.

Incidentally, in other embodiments of this disclosure, it may also be possible to have all the memory sub-blocks 111 to 114 receive and share the same ground selection signal, or have the memory sub-blocks 111 to 113 receive the same first ground selection signal, while the memory sub-block 114 receives another second ground selection signal. The related configuration method may be determined at the discretion of the designer, and there is no particular limit.

On the other hand, when the reading periods Tr1 to Tr4 are for performing reading operations on the last word line, after the reading period Tr4, the controller 120 may have the memory device 100 enter the recovery period Trv. Here, the operation method of the recovery period Trv is the same as that in the embodiment of FIG. 3 and will not be repeated here.

It is worth noting that in the aforementioned embodiments of FIG. 4 and FIG. 5, when the reading periods Tr1 to Tr4 are for performing reading operations on the last word line, after the completion of the reading period Tr4, the process may enter the recovery period Trv. For related details, reference may be made to the explanations of FIG. 3 and FIG. 6, which should be understood by those skilled in the art and so will not be repeated here.

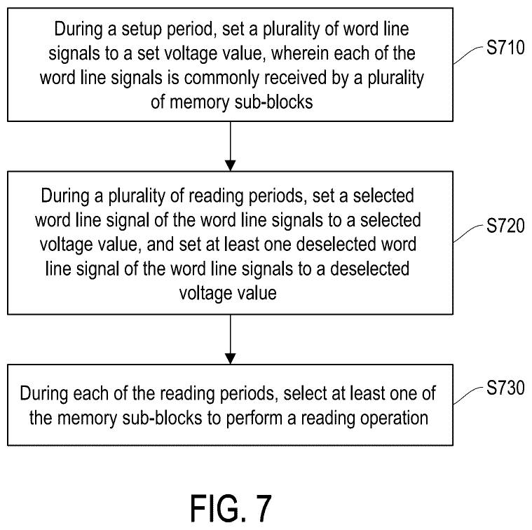

Referring to FIG. 7, FIG. 7 is a flowchart of a reading method of a memory device according to an embodiment of the disclosure. In S710, during the setup period, a plurality of word line signals are set to a set voltage value, wherein each of the word line signals is commonly received by a plurality of memory sub-blocks in the memory block. In S720, during a plurality of reading periods, a selected word line signal of the word line signals is set to a selected voltage value, and at least one deselected word line signal of the word line signals is set to a deselected voltage value. In S730, during each of the reading periods, at least one of the memory sub-blocks is selected to perform a reading operation, wherein the reading periods are a plurality of consecutive time periods after the setup period.

The implementation details of the above steps have been described in detail in the foregoing multiple embodiments and implementations and will not be repeated here.

In summary of the foregoing, in the memory device of the disclosure, after a setup period, a plurality of memory sub-blocks of the memory block are sequentially selected to perform reading operations without adjusting the voltage value of the word line signal. This method may effectively reduce the time required for sequential reading operations of the memory device, thereby improving the reading speed of the memory device.

What is claimed is:

1. A reading method, adapted for a memory block having a plurality of memory sub-blocks, comprising:
during a setup period, setting a plurality of word line signals to a set voltage value, wherein each of the word line signals is commonly received by the memory sub-blocks;
during a plurality of reading periods, setting a selected word line signal of the word line signals to a selected voltage value, and setting at least one deselected word line signal of the word line signals to a deselected voltage value; and
during each of the reading periods, selecting at least one of the memory sub-blocks to perform a reading operation,
wherein the reading periods are a plurality of consecutive time periods after the setup period.

2. The reading method according to claim 1, further comprising:
during the reading periods, enabling each of a plurality of memory string selection signals to select at least one of the memory sub-blocks for performing the reading operation.

3. The reading method according to claim 2, further comprising:
during the reading periods, enabling ground selection signals corresponding to at least one of the memory sub-blocks selected for performing the reading operation.

4. The reading method according to claim 3, wherein a number of the ground selection signals is equal to or less than a number of the memory string selection signals.

5. The reading method according to claim 3, further comprising:
during a recovery period after the reading periods, pulling down all of the word line signals, the memory string selection signals, and the ground selection signals to a reference voltage.

6. The reading method according to claim 5, further comprising:
when the selected word line signal is a last word line signal, entering the recovery period after the reading periods.

7. The reading method according to claim 1, further comprising:
during a switching period after the reading periods, first coupling a plurality of word lines together to equal the selected word line signal and the at least one deselected word line signal to a same voltage value, and then pulling up the selected word line signal and the at least one deselected word line signal to the deselected voltage value.

8. The reading method according to claim 1, further comprising:
during a switching period after the reading periods, pulling up the selected word line signal to the deselected voltage value.

9. The reading method according to claim 1, further comprising:
after a switching period following the reading periods, changing another one of the word line signals to be the selected word line signal.

10. A memory device, comprising:
a memory block, comprising a plurality of memory sub-blocks, wherein the memory block receives a plurality of word line signals through a plurality of word lines respectively, each of the word line signals is commonly received by the memory sub-blocks, and the memory sub-blocks respectively receives a plurality of memory string selection signals; and
a controller, coupled to the memory block, wherein the controller is configured to:
during a setup period, set the word line signals to a set voltage value;
during a plurality of reading periods, set a selected word line signal of the word line signals to a selected voltage value, and set at least one deselected word line signal of the word line signals to a deselected voltage value; and
during each of the reading periods, select at least one of the memory sub-blocks to perform a reading operation,
wherein the reading periods are a plurality of consecutive time periods after the setup period.

11. The memory device according to claim 10, wherein the controller is further configured to:
during the reading periods, enable at least one of the memory string selection signals to select each of the memory sub-blocks for performing the reading operation.

12. The memory device according to claim 11, wherein the controller is further configured to:
during the reading periods, enable ground selection signals corresponding to at least one of the memory sub-blocks selected for performing the reading operation.

13. The memory device according to claim 12, wherein a number of the ground selection signals is equal to or less than a number of the memory string selection signals.

14. The memory device according to claim 12, wherein the controller is further configured to:
during a recovery period after the reading periods, pull down all of the word line signals, the memory string selection signals, and the ground selection signals to a reference voltage.

15. The memory device according to claim 14, wherein the controller is further configured to:
when the selected word line signal is a last word line signal, enter the recovery period after the reading periods.

16. The memory device according to claim 10, wherein the controller is further configured to:
during a switching period after the reading periods, first couple a plurality of word lines together to equal the selected word line signal and the at least one deselected word line signal to a same voltage value, and then pull up the selected word line signal and the at least one deselected word line signal to the deselected voltage value.

17. The memory device according to claim 10, wherein the controller is further configured to:
during a switching period after the reading periods, pull up the selected word line signal to the deselected voltage value.

18. The memory device according to claim 10, wherein the controller is further configured to:
after a switching period following the reading periods, change another one of the word line signals to be the selected word line signal.
